(19) United States
(12) Patent Application Publication
(10) Pub. No.: US 2025/0151236 A1
(43) Pub. Date: May 8, 2025

(54) HEATSINK DESIGN WITH VARIABLE EFFECTIVE HEAT TRANSFER COEFFICIENT

(71) Applicant: Alliance for Sustainable Energy, LLC, Golden, CO (US)

(72) Inventors: Bidzina KEKELIA, Littleton, CO (US); Douglas John DEVOTO, Boulder, CO (US); Justine Emily COUSINEAU, Lakewood, CO (US)

(21) Appl. No.: 18/934,352

(22) Filed: Nov. 1, 2024

Related U.S. Application Data
(60) Provisional application No. 63/595,429, filed on Nov. 2, 2023.

(51) Int. Cl. H05K 7/20

(52) U.S. Cl. CPC H05K 7/2039; H05K 7/209

(57) ABSTRACT

Heat sink devices which gradually increase the effective heat transfer coefficient (HTC) of a cooling fluid flowing along a row of power electronics devices are described. The heat sink devices may allow substantially uniform cooling of the plurality of power electronics devices, regardless of the temperature of the cooling fluid when it contacts them. The heat sink devices allow the HTC to be increased as needed down the row of power electronics devices resulting in power electronics devices cooled to substantially the same temperatures. The heat sink devices may include fins.

### CROSS-REFERENCE TO RELATED APPLICATIONS

This application claims priority from U.S. Provisional Patent Application No. 63/595,429 filed on Nov. 2, 2023, the contents of which are incorporated herein by reference in their entirety.

### CONTRACTUAL ORIGIN

This invention was made with government support under Contract No. DE-AC36-08GO28308 awarded by the Department of Energy. The government has certain rights in this invention.

### BACKGROUND

There are often several power devices mounted on a printed circuit board (PCB). When cooling power devices in electronics power conversion devices, the power electronics device closest to the inlet is often cooled much more effectively than the last power electronics device in the row. This is because the first power electronics device experiences a lower coolant temperature, and the last device experiences a higher coolant temperature (as the coolant picks up heat from the prior power electronics devices). This temperature disbalance negatively affects overall power conversion device (i.e., inverter) performance, as the power electronics devices are unevenly cooled. Thus, there remains a need to cool multiple power devices consistently.

### SUMMARY

An aspect of the present disclosure is a device including a first end in contact with a first power electronics device, a second end in contact with a second power electronics device, a length spanning between the first end and the second end, a first fin, and, a second fin, in which a cooling fluid is configured to enter the device at the first end, the first fin is located at the first end, the second fin is located at the second end, and the cooling fluid is configured to cool the first power electronics device and the second power electronics device to approximately the same temperature by flowing through the device. In some embodiments, the device also includes a third fin, in which the third fin is located at the second end. In some embodiments, the first fin spans the length. In some embodiments, the first fin has a first height at the first end and a second height at the second end, and the first height is less than the second height. In some embodiments, the first height is in the range of approximately 0.1 mm to approximately 100.0 mm. In some embodiments, the device is made of a substantially conductive material. In some embodiments, the substantially conductive material includes at least one of aluminum, silver, copper, gold, zinc, nickel, iron, or platinum. In some embodiments the substantially conductive material includes brass or bronze. In some embodiments, the substantially conductive material includes ceramic material.

An aspect of the present disclosure is a method including forming a heat sink device, in which the heat sink device includes a first end in contact with a first power electronics device. a second end in contact with a second power electronics device, a length spanning between the first end and the second end, a first fin, and a second fin, in which a cooling fluid is configured to enter the device at the first end, and the first fin is located at the first end, the second fin is located at the second end, and the cooling fluid is configured to cool the first power electronics device and the second power electronics device to approximately the same temperature by flowing through the heat sink device. In some embodiments, the forming includes extruding the heat sink device using additive manufacturing. In some embodiments, the forming includes milling within the housing to form the first fin and the second fin. In some embodiments, the heat sink device also includes a third fin, in which the third fin is located at the second end. In some embodiments, the first fin spans the length. In some embodiments, the first fin has a first height at the first end and a second height at the second end, and the first height is less than the second height. In some embodiments, the first height is in the range of approximately 0.1 mm to approximately 100.0 mm. In some embodiments, the heat sink device includes a substantially conductive material. In some embodiments, the substantially conductive material includes at least one of aluminum, silver, copper, gold, zinc, nickel, iron, or platinum. In some embodiments, the substantially conductive material includes brass or bronze. In some embodiments, the substantially conductive material includes a ceramic material.

### BRIEF DESCRIPTION OF THE DRAWINGS

Some embodiments of the present disclosure are illustrated in the referenced figures of the drawings. It is intended that the embodiments and figures disclosed herein are to be considered illustrative rather than limiting.

FIG. 1 illustrates the flow of a cooling fluid through a heat sink device as described in some aspects of the present disclosure.

FIGS. 2A-B illustrates an exemplary embodiment of a heat sink device having fins of increasing height along the length of the heat sink in an isometric (FIG. 2A) and side cut-away (FIG. 2B) view, according to some aspects of the present disclosure.

FIG. 3 illustrates an exemplary embodiment of a heat sink device having increasing fin density along the length of the heat sink, according to some aspects of the present disclosure.

### REFERENCE NUMERALS

100 heat sink device
105 first end
110 second end
115 length
120 fin
125 height
130 cooling fluid
135 housing
200 power electronics device

### DETAILED DESCRIPTION

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

Among other things, the present disclosure relates to heat sink devices which gradually increase the effective heat transfer coefficient (HTC) of a cooling fluid flowing along a row of power electronics devices. The heat sink devices described herein may allow substantially uniform cooling of the plurality of power electronics devices, regardless of the temperature of the cooling fluid when it contacts them. The heat sink devices described herein allow the HTC to be varied and adjusted as needed down the row of power electronics devices resulting in power electronics devices kept at substantially the same temperatures. The heat sink devices described herein may include fins or other surface enhancements to help with the cooling.

HTC is the proportionality coefficient of the heat flux and the thermodynamic driving force for the flow of heat (i.e., the temperature difference). HTC indicates how well heat is conducted through a medium. For the heat sink device of the present disclosure, a higher HTC indicates better heat flow (i.e., better removal of heat from the power electronics devices). Typically, the cooling fluid is the coldest when entering a heat sink, resulting in a higher HTC on the first power electronics devices and a lower HTC for later power electronics devices. This also results in inconsistent cooling, as the later power electronics devices experience a hotter cooling fluid. The heat sink device described herein may allow the HTC to remain substantially constant or increase along the length of the heat sink device and cool the power electronics devices to substantially similar temperatures. This means that the heat flow through the heat sink device (and thus the heat removal or cooling of the power electronics devices) may be substantially consistent along the length of the heat sink device, resulting in a relatively consistent cooling of the power electronics devices.

Simple heat transfer is related to the surface area in contact between the two materials and the temperature difference between the two materials (ΔT). As cooling fluid flows through a typical heat sink to cool a plurality of power electronics devices, it increases in temperature, meaning the later power electronics devices have a lower ΔT with the cooling fluid than the earlier power electronics devices. To address this, the present disclosure increases the surface area between the power electronics devices and the cooling fluid by increasing the number and/or the height of the fins in the heat sink that are in contact with the cooling fluid. This may result in the plurality of power electronics devices being cooled substantially evenly (i.e., to substantially the same temperature).

As used herein, “power electronics” may refer to metal oxide semiconductor field-effect transistors (MOSFET), insulated-gate bipolar transistors (IGBT), direct bonded copper (DBC) substrates, high frequency switch mode power supplies (SMPS), and/or other power inverters, converters, rectifiers or modules. The power electronics devices may be arranged in series (i.e., in a single line) or in a grid (i.e., in at least two rows).

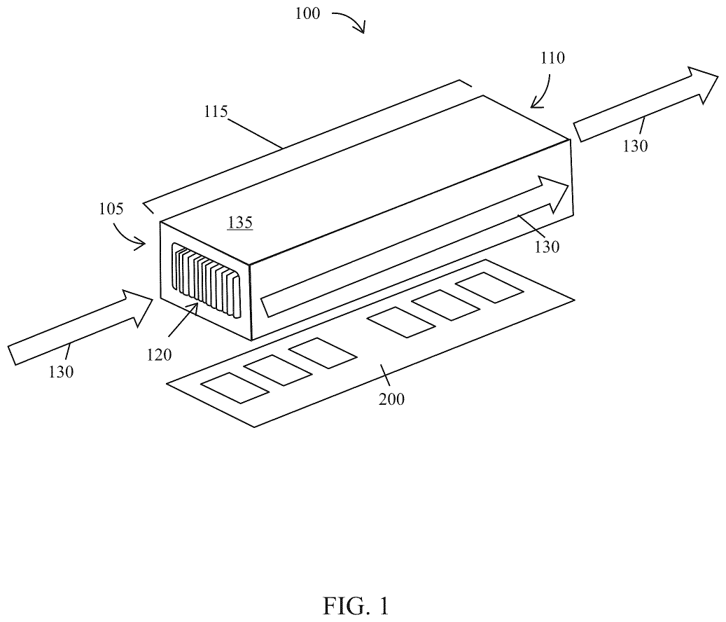

FIG. 1 illustrates the flow of a cooling fluid 130 through a heat sink device 100 as described in some aspects of the present disclosure. As indicated by the arrows, the cooling fluid 130 enters the first end 105 of the housing 135 of the heat sink device 100, then as the cooling fluid 130 moves along the length 115 of the heat sink device 100 it cools the power electronics devices 200 before exiting the heat sink device 100 at the second end 110. In typical heat sink devices, the heating is inconsistent along the length 115 of the heat sink device 100, as the coolest cooling fluid 130 is at the first end 105 of the heat sink device 100 and the cooling fluid 130 gains heat along the length 115 of the heat sink device 100 (i.e., increases temperature and becomes less effective at cooling the power electronics devices 200). In the heat sink device 100 of the present disclosure, a cooling fluid 130 flows through the heat sink device 100, but the fins 120 and their features provide an increased surface area for cooling, resulting in substantially more uniform cooling of a plurality of power electronics devices 200 compared to traditional heat sinks.

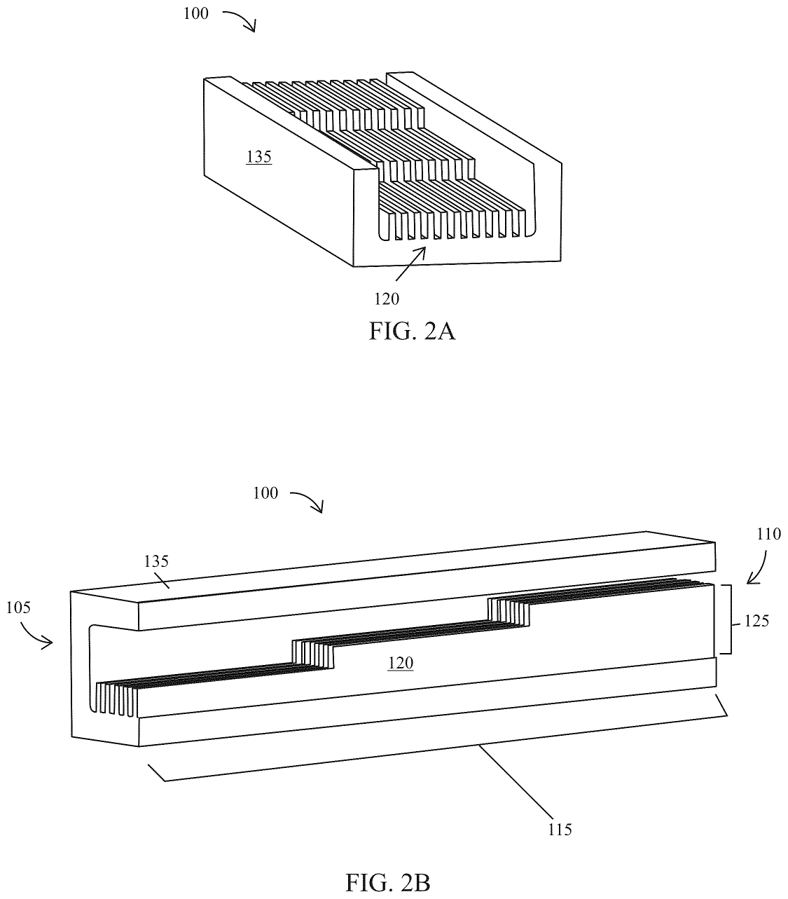

FIG. 2 illustrates an exemplary embodiment of a heat sink device 100 having fins 120 of increasing height 125 along the length 115 of the heat sink device 100, according to some aspects of the present disclosure. Each fin 120 may be a substantially solid piece of planar material for removing heat from the power electronics devices 200 (which may be in contact with the heat sink device 100). The fins 120 may be made of a substantially conductive material, such as a metal and/or metal alloy or a mixture of multiple substantially conductive metals. Exemplary substantially conductive materials include aluminum, silver, copper, gold, zinc, nickel, iron, platinum, brass, or bronze. Other exemplary substantially conductive materials may include thermally enhanced polymers or ceramics. In some embodiments, the fins 120 may optimize the cooling fluid 130 pathway in such a way that the fins 120 may be made of a slightly insulative material such as plastic. In the embodiment shown in FIG. 2, the fins 120 are shown to increase in height 125 along the length 115 of the heat sink device 100. That is, the fins 120 are shorter closer to the first end 105 (i.e., where the cooling fluid 130 enters) and taller closer to the second end 110 (i.e., where the cooling fluid 130 exits).

In some embodiments, this height 125 increase may be done in a step wise fashion (as shown in FIG. 2) whereby after a certain distance (for example, approximately every about 0.5 mm to about 5 mm the height 125 of the fins 120 may increase by approximately 1 mm). In some embodiments, this may be done using fins 120 that gradually increase in height 125 (i.e., in a curved, angled, or sloped fashion). The example shown in FIG. 2 shows three “steps” or increases in height 125 in the fins 120, however, more or less steps or increases may be used. The number of steps or increases may be based on the heat of the power electronics device 200, the size of the height 125 increase at each step, and/or the length 115 of the heat sink device 100, among other factors. The example shown in FIG. 2 shows steps or increases which are substantially the same portion of the length 115 and height 125, but in other embodiments the “steps” (i.e., height 125 increases) may be of inconsistent length and/or height. That is, each step may not be of the same portion of the length 115 and/or height 125.

In some embodiments, the fins 120 may have a height 125 in the range of about 0.1 mm to about 100 mm. The “steps” or amounts the height may increase may be in the range of about 0.01 mm to about 10 mm. The height 125 of the fins 120 may depend on the cooling needs of the heat sink device 100 and/or size constraints of the space in which the heat sink device 100 is intended to operate.

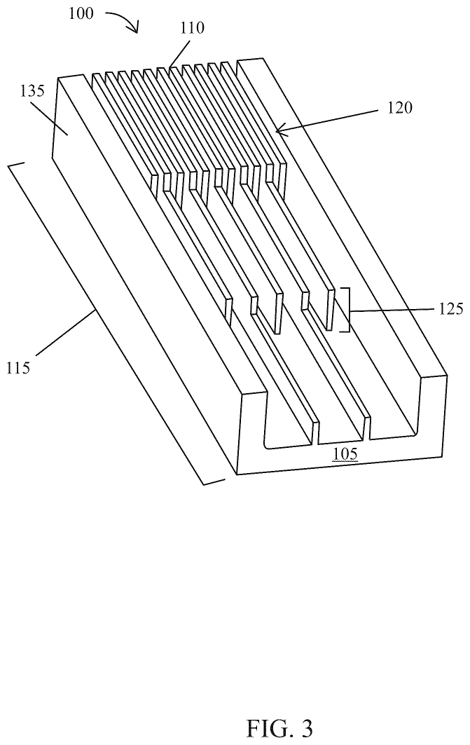

In the example shown in FIG. 2, the same number of fins 120 are present throughout the length 115 of the heat sink device 100. Indeed, each individual fin 120 may span the length 115 of the heat sink device 100. However, as shown in FIG. 3, in some embodiments, the number of fins 120 may vary along the length 115 of the heat sink device 100.

In some embodiments, the housing 135 may be made of a substantially conductive material, such as a metal and/or metal alloy or a mixture of multiple substantially conductive metals. Exemplary substantially conductive materials include aluminum, silver, copper, gold, zinc, nickel, iron, platinum, brass, or bronze. Other exemplary substantially conductive materials may include thermally enhanced polymers or ceramic materials. The housing 135 may have a substantially rectangular or circular cross section. The housing 135 may act as a tube or tunnel to contain the cooling fluid 130 and direct it towards the fins 120 and the power electronics devices 200. In some embodiments, the housing 135 and the fins 120 may be made of the same material, as they may be manufactured by extruding and/or by additive manufacturing (i.e., 3D printing) or casting. In some embodiments, the heat sink device 100 may be made using additive manufacturing or casting then milled (or machined) to cut out material within the housing 135 to form the fins 120 and/or adjust the height 125 of the fins.

FIG. 3 illustrates an exemplary embodiment of a heat sink device 100 having increasing fin 120 density along the length 115 of the heat sink device 100, according to some aspects of the present disclosure. In this embodiment, the number of fins 120 and the height 125 of the fins 120 increases along the length 115 of the heat sink device 100. That is, the fins 120 are shorter and there are less fins 120 closer to the first end 105 (i.e., where the cooling fluid 130 enters) and the fins 120 are taller and there are more of them closer to the second end 110 (i.e., where the cooling fluid 130 exits).

In some embodiments, this increase in height 125 and density of fins 120 may be in a step wise fashion (as shown in FIG. 3) whereby after a certain distance (for example, approximately every about 0.5 mm to about 5 mm the height 125 of the fins 120 may increase by approximately 1 mm and the number of fins 120 may double). In some embodiments, this may be done using fins 120 that gradually increase in height 125 (i.e., in a curved, angled, or sloped fashion). The number of fins 120 present in the heat sink device 100 may be based on the size of the heat sink device 100, the temperature of the power electronics devices 200, the desired amount of cooling of the power electronics devices 200, and/or the temperature of the cooling fluid 130 when it enters the heat sink device 100, among other factors. The example shown in FIG. 3 includes two fins 120 near the first end 105 of the heat sink device 100, increasing to eleven fins 120 near the second end 110 of the heat sink device 100, but other numbers of fins 120 could be used.

In some embodiments, the fins 120 may have a thickness in the range of approximately 0.1 mm to approximately 5.0 mm. In some embodiments, the thickness of the fins 120 may be in the range of about 0.5 mm to about 2.0 mm. In some embodiments, each fin 120 may be substantially similar in thickness. In some embodiments, the fins 120 may have varying thicknesses (that is, each fin 120 may not be substantially similar in thickness to another fin 120). In some embodiments, a single fin 120 may vary in thickness along the length 115 of the heat sink device 100 (for example, increasing in thickness along the length 115 of the heat sink device 100).

In some embodiments, the heat sink may be manufactured using an extrusion process. In some embodiments, the heat sink device 100 may be manufactured using additive manufacturing (i.e., 3D printing). In some embodiments, the heat sink device 100 may be manufactured by cutting a substantially solid block to form the housing 135 and fins 120. In these forms of manufacture the fins 120 may be connected to the housing 135 without a “seam” or other connection mechanism—they may be one piece with the heat sink. The number of fins 120 and height 125 of fins 120 may be determined both by the cooling needs of the heat sink device 100 or by the ease of manufacture. Underneath the fins 120 and along the length 115 of the heat sink 100, the heat sink 100 may have a base (for example an exterior surface of the housing 135) which is in direct physical contact with the power electronics devices 200.

In some embodiments, the cooling fluid 130 may be water, ethylene glycol, propylene glycol, methanol, and/or mineral oil. In some embodiments, the cooling fluid 130 may be automotive oil. In some embodiments, the cooling fluid 130 may be a refrigerant (such as R-410A, R-470C, and/or R-502) even though the cooling process enabled by the heat sink device 100 does not rely on a phase change of the cooling fluid 130.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

What is claimed is:

1. A device comprising:
a first end in contact with a first power electronics device;
a second end in contact with a second power electronics device;
a length spanning between the first end and the second end;
a first fin; and
a second fin; wherein:
a cooling fluid is configured to enter the device at the first end,
the first fin is located at the first end,
the second fin is located at the second end, and
the cooling fluid is configured to cool the first power electronics device and the second power electronics device to approximately the same temperature by flowing through the device.

2. The device of claim 1, further comprising:
a third fin; wherein:
the third fin is located at the second end.

3. The device of claim 1, wherein:
the first fin spans the length.

4. The device of claim 3, wherein:
the first fin has a first height at the first end and a second height at the second end, and
the first height is less than the second height.

5. The device of claim 4, wherein:
the first height is in the range of approximately 0.1 mm to approximately 100.0 mm.

6. The device of claim 1, wherein:
the device comprises a substantially conductive material.

7. The device of claim 6, wherein:
the substantially conductive material comprises at least one of aluminum, silver, copper, gold, zinc, nickel, iron, or platinum.

8. The device of claim 6, wherein:
the substantially conductive material comprises brass or bronze.

9. The device of claim 6, wherein:
the substantially conductive material comprises a ceramic material.

10. A method comprising:
forming a heat sink device; wherein:
the heat sink device comprises:
a first end in contact with a first power electronics device;
a second end in contact with a second power electronics device;
a length spanning between the first end and the second end;
a first fin; and
a second fin; wherein:
a cooling fluid is configured to enter the device at the first end, and
the first fin is located at the first end,
the second fin is located at the second end, and
the cooling fluid is configured to cool the first power electronics device and the second power electronics device to approximately the same temperature by flowing through the heat sink device.

11. The method of claim 10, wherein:
the forming comprises extruding the heat sink device using additive manufacturing.

12. The method of claim 10, wherein:
the forming comprises milling within the housing to form the first fin and the second fin.

13. The method of claim 10, wherein:
the heat sink device further comprises:
a third fin; wherein:
the third fin is located at the second end.

14. The method of claim 10, wherein:
the first fin spans the length.

15. The method of claim 14, wherein:
the first fin has a first height at the first end and a second height at the second end, and
the first height is less than the second height.

16. The method of claim 15, wherein:
the first height is in the range of approximately 0.1 mm to approximately 100.0 mm.

17. The method of claim 10, wherein:
the heat sink device comprises a substantially conductive material.

18. The method of claim 17, wherein:
the substantially conductive material comprises at least one of aluminum, silver, copper, gold, zinc, nickel, iron, or platinum.

19. The method of claim 17, wherein:
the substantially conductive material comprises brass or bronze.

20. The method of claim 17, wherein:
the substantially conductive material comprises a ceramic material.
